(19) United States
(12) Patent Application Publication
(10) Pub. No.: US 2011/0025404 A1
(43) Pub. Date: Feb. 3, 2011

(54) SWITCHES WITH VARIABLE CONTROL VOLTAGES

(75) Inventor: Marco Cassia, San Diego, CA (US)

Correspondence Address: QUALCOMM INCORPORATED, 5775 MOREHOUSE DR., SAN DIEGO, CA, 92121, US

(73) Assignee: QUALCOMM INCORPORATED, San Diego, CA (US)

(21) Appl. No.: 12/623,232

(22) Filed: Nov. 20, 2009

Related U.S. Application Data
(60) Provisional application No. 61/229,589, filed on Jul. 29, 2009.
(60) Provisional application No. 61/229,649, filed on Jul. 29, 2009.

(51) Int. Cl. H03K 17/687

(52) U.S. Cl. 327/436

(57) ABSTRACT

Switches with variable control voltages and having improved reliability and performance are described. In an exemplary design, an apparatus includes a switch, a peak voltage detector, and a control voltage generator. The switch may be implemented with stacked transistors. The peak voltage detector detects a peak voltage of an input signal provided to the switch. In an exemplary design, the control voltage generator generates a variable control voltage to turn off the switch based on the detected peak voltage. In another exemplary design, the control voltage generator generates a variable control voltage to turn on the switch based on the detected peak voltage. In yet another exemplary design, the control voltage generator generates a control voltage to turn on the switch and attenuate the input signal when the peak voltage exceeds a high threshold.

### I. CLAIM OF PRIORITY UNDER 35 U.S.C. §119

The present application for patent claims priority to Provisional U.S. Application Ser. No. 61/229,589, entitled “SWITCHPLEXER VSWR ACTIVE PROTECTION,” filed Jul. 29, 2009, and Provisional U.S. Application Ser. No. 61/229,649, entitled “SWITCHPLEXER ADAPTIVE BIAS,” filed Jul. 29, 2009, both assigned to the assignee hereof, and expressly incorporated herein by reference.

### BACKGROUND

I. Field

The present disclosure relates generally to electronics, and more specifically to switches.

II. Background

Switches are commonly used in various electronics circuits such as a transmitter in a wireless communication device. Switches may be implemented with various types of transistors such as metal oxide semiconductor (MOS) transistors. A switch may receive an input signal at one source/drain terminal and a control signal at a gate terminal. The switch may pass the input signal to the other source/drain terminal if it is turned on by the control signal and may block the input signal if it is turned off by the control signal. It may be desirable to obtain good performance and high reliability for the switch.

### BRIEF DESCRIPTION OF THE DRAWINGS

FIG. 1 shows a block diagram of a wireless communication device.

FIG. 2 shows a power amplifier (PA) module and switches/duplexers.

FIG. 3 shows a switch implemented with stacked MOS transistors.

FIG. 4A shows two switches coupled to a common node.

FIG. 4B shows voltages for a switch that is turned off.

FIG. 5 shows two switches coupled to a common node, with one switch having a variable off control voltage.

FIG. 6 shows two switches coupled to a common node, with one switch having a variable off control voltage and the other switch having a variable on control voltage.

FIG. 7 shows switches being turned off or on based on detected peak voltage.

FIG. 8 shows a peak voltage detector.

FIG. 9 shows a process for controlling a switch.

### DETAILED DESCRIPTION

The word “exemplary” is used herein to mean “serving as an example, instance, or illustration.” Any design described herein as “exemplary” is not necessarily to be construed as preferred or advantageous over other designs.

Switches with variable control voltages and having improved reliability and possibly better performance are described herein. These switches may be used for various electronics devices such as wireless communication devices, cellular phones, personal digital assistants (PDAs), handheld devices, wireless modems, laptop computers, cordless phones, Bluetooth devices, consumer electronics devices, etc. For clarity, the use of the switches in a wireless communication device is described below.

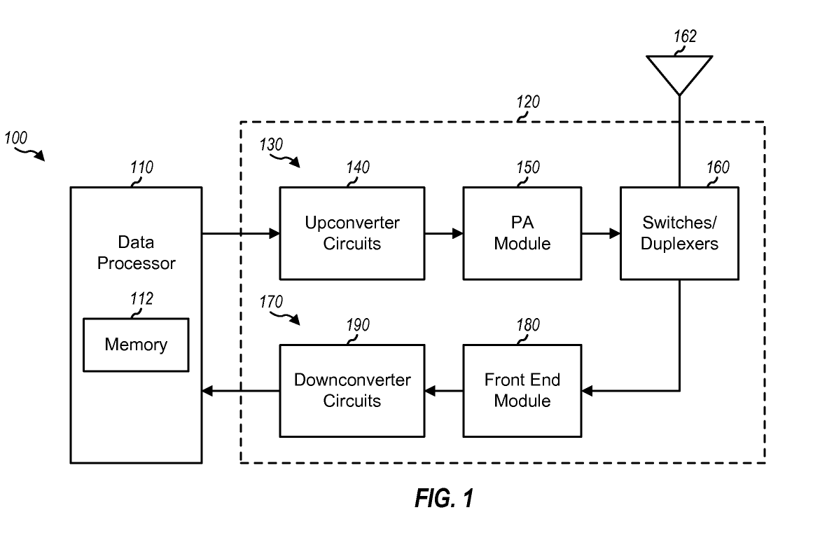

FIG. 1 shows a block diagram of an exemplary design of a wireless communication device 100. In this exemplary design, wireless device 100 includes a data processor 110 and a transceiver 120. Transceiver 120 includes a transmitter 130 and a receiver 170 that support bi-directional communication.

In the transmit path, data processor 110 may process (e.g., encode and modulate) data to be transmitted and provide an output baseband signal to transmitter 130. Within transmitter 130, upconverter circuits 140 may process (e.g., amplify, filter, and frequency upconvert) the output baseband signal and provide an upconverted signal. Upconverter circuits 140 may include amplifiers, filters, mixers, etc. A power amplifier (PA) module 150 may amplify the upconverted signal to obtain the desired output power level and provide an output radio frequency (RF) signal, which may be routed through switches/duplexers 160 and transmitted via an antenna 162.

In the receive path, antenna 162 may receive RF signals transmitted by base stations and/or other transmitter stations and may provide a received RF signal, which may be routed via switches/duplexers 160 and provided to receiver 170. Within receiver 170, a front end module 180 may process (e.g., amplify and filter) the received RF signal and provide an amplified RF signal. Front end module 180 may include low noise amplifiers (LNAs), filters, etc. Downconverter circuits 190 may further process (e.g., frequency downconvert, filter, and amplify) the amplified RF signal and provide an input baseband signal to data processor 110. Downconverter circuits 190 may include mixers, filters, amplifiers, etc. Data processor 110 may further process (e.g., digitize, demodulate, and decode) the input baseband signal to recover transmitted data.

FIG. 1 shows an exemplary design of transmitter 130 and receiver 170. All or a portion of transmitter 130 and/or all or a portion of receiver 170 may be implemented on one or more analog ICs, RF ICs (RFICs), mixed-signal ICs, etc.

Data processor 110 may generate controls for the circuits and modules in transmitter 130 and receiver 170. The controls may direct the operation of the circuits and modules to obtain the desired performance. Data processor 110 may also perform other functions for wireless device 100, e.g., processing for data being transmitted or received. A memory 112 may store program codes and data for data processor 110. Data processor 110 may be implemented on one or more application specific integrated circuits (ASICs) and/or other ICs.

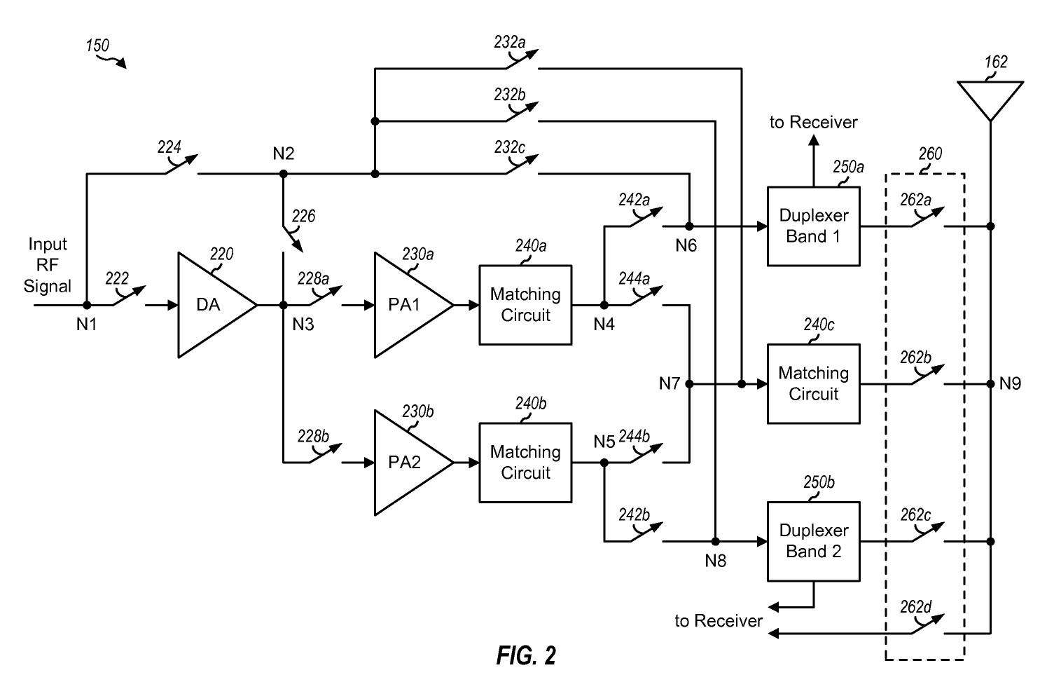

FIG. 2 shows a block diagram of an exemplary design of PA module 150 and switches/duplexers 160 in FIG. 1. In the exemplary design shown in FIG. 2, switches/duplexers 160 include duplexers 250a and 250b and a switchplexer 260. PA module 150 includes the remaining circuits in FIG. 2.

Within PA module 150, a switch 222 is coupled between node N1 and the input of a driver amplifier (DA) 220, and the output of driver amplifier 220 is coupled to node N3. An input RF signal is provided to node N1. A switch 224 is coupled between nodes N1 and N2, and a switch 226 is coupled between nodes N2 and N3. A switch 228a is coupled between node N3 and the input of a first power amplifier (PA1) 230a, and a switch 228b is coupled between node N3 and the input of a second power amplifier (PA2) 230b. A matching circuit 240a is coupled between the output of power amplifier 230a and node N4, and a matching circuit 240b is coupled between the output of power amplifier 230b and node N5. Switches 232a, 232b and 232c have one end coupled to node N2 and the other end coupled to nodes N7, N8 and N6, respectively. Switches 242a and 244a have one end coupled to node N4 and the other end coupled to nodes N6 and N7, respectively. Switches 242b and 244b have one end coupled to node N5 and the other end coupled to nodes N8 and N7, respectively. A matching circuit 240c is coupled in series with a switch 262b, and the combination is coupled between nodes N7 and N9.

Duplexer 250a for band 1 has its transmit port coupled to node N6, its receive port coupled to a receiver (e.g., front end module 180 in FIG. 1), and its common port coupled to node N9 via a switch 262a. Duplexer 250b for band 2 has its transmit port coupled to node N8, its receive port coupled to the receiver, and its common port coupled to node N9 via a switch 262c. A switch 262d is coupled between node N9 and the receiver and may be used to support time division duplexing (TDD), e.g., for Global System for Mobile Communications (GSM). Antenna 162 is coupled to node N9.

Driver amplifier 220 may be selected/enabled to provide signal amplification or may be bypassed. Each power amplifier 230 may also be selected to provide power amplification or may be bypassed. Matching circuit 240a may provide output impedance matching for power amplifier 230a, and matching circuit 240b may provide output impedance matching for power amplifier 230b. Matching circuits 240a and 240b may each provide a target input impedance (e.g., 4 to 6 Ohms) and a target output impedance (e.g., 50 Ohms). Matching circuit 240c may provide impedance matching for matching circuits 240a and 240b when both power amplifiers 230a and 230b are enabled and switches 244a and 244b are closed. Matching circuits 240a, 240b and 240c may also provide filtering to attenuate undesired signal components at harmonic frequencies.

PA module 150 may support a number of operating modes. Each operating mode may be associated with a different signal path from node N1 to node N9 via zero or more amplifiers. One operating mode may be selected at any given moment. The signal path for the selected operating mode may be obtained by properly controlling the switches within transmitter 150. For example, a high power mode may be associated with a signal path from node N1 through switch 222, driver amplifier 220, switches 228a and 228b, power amplifiers 230a and 230b, matching circuits 240a and 240b, switches 244a and 244b, matching circuit 240c, and switch 262b to antenna 162. A medium power mode may be associated with a signal path from node N1 through switch 222, driver amplifier 220, switch 228a, power amplifier 230a, matching circuit 240a, switch 244a, matching circuit 240c, and switch 262b to antenna 162. A low power mode may be associated with a signal path from node N1 through switch 222, driver amplifier 220, switches 226 and 232a, matching circuit 240c, and switch 262b to antenna 162. A very low power mode may be associated with a signal path from node N1 through switches 224 and 232a, matching circuit 240c, and switch 262b to antenna 162. Other operating modes may also be supported.

In the exemplary design shown in FIG. 2, switches may be used to route RF signals and support multiple operating modes. The switches may be implemented with MOS transistors, transistors of other types, and/or other circuit components. For clarity, switches implemented with MOS transistors are described below.

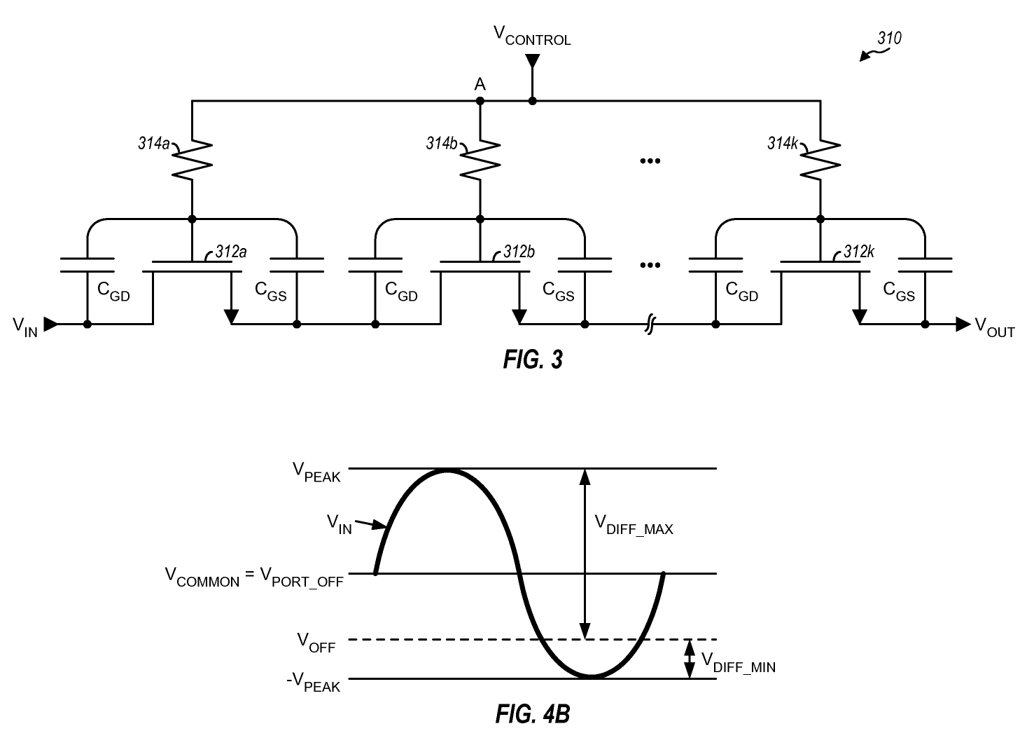

FIG. 3 shows a schematic diagram of a switch 310 implemented with stacked N-channel MOS (NMOS) transistors. Within switch 310, K NMOS transistors 312a through 312k are coupled in a stacked configuration (or in series), where K may be any integer value greater than one. Each NMOS transistor 312 (except for the last NMOS transistor 312k) has its source coupled to the drain of a following NMOS transistor. The first NMOS transistor 312a has its drain receiving an input RF signal (V_{IN}), and the last NMOS transistor 312k has its source providing an output RF signal (V_{OUT}). Each NMOS transistor 312 may be implemented with a symmetric structure, and the source and drain of each NMOS transistor may be interchangeable. K resistors 314a through 314k have one end coupled to node A and the other end coupled to the gate of NMOS transistors 312a through 312k, respectively. A control signal (V_{CONTROL}) is applied to node A to turn on or off NMOS transistors 312.

Ideally, each NMOS transistor 312 should pass the V_{IN} signal when it is turned on and should block the V_{IN} signal when it is turned off. However, each NMOS transistor 312 has parasitic gate-to-source capacitance (C_{GS}) as well as parasitic gate-to-drain capacitance (C_{GD}), as shown in FIG. 3. For simplicity, other parasitic capacitances may be assumed to be negligible. For example, the source-to-bulk, source-to-substrate, drain to-bulk, and drain-to-substrate parasitic capacitances may be assumed to be negligible, or their effects may be mitigated. When a given NMOS transistor 312 is turned on, a portion of the V_{IN} signal passes through a leakage path via the C_{GD} and Cgs capacitors to the V_{CONTROL} signal source, which may have a low impedance. To reduce this signal loss, the gate of each NMOS transistor 312 may be RF floated via the associated resistor 314. Resistors 314a through 314k may have the same resistor value, which may be relatively large, e.g., in the kilo Ohm (kΩ) range. When a given NMOS transistor 312 is turned on, the leakage path is via the parasitic C_{GD} and Cgs capacitors as well as resistor 314 to the V_{CONTROL} signal source. The high resistance of resistor 314 may essentially float the gate of NMOS transistor 312 at RF frequency, which may then reduce signal loss. Although not shown in FIG. 3, the V_{CONTROL} signal may be applied to one end of an additional resistor having its other end coupled to node A. This additional resistor may further reduce signal loss and improve switching performance.

FIG. 3 shows a switch implemented with NMOS transistors. A switch may also be implemented with P-channel MOS (PMOS) transistors or transistors of other types. For simplicity, switches implemented with NMOS transistors are described below. The techniques described herein may also be applied to switches implemented with PMOS and/or transistors of other types.

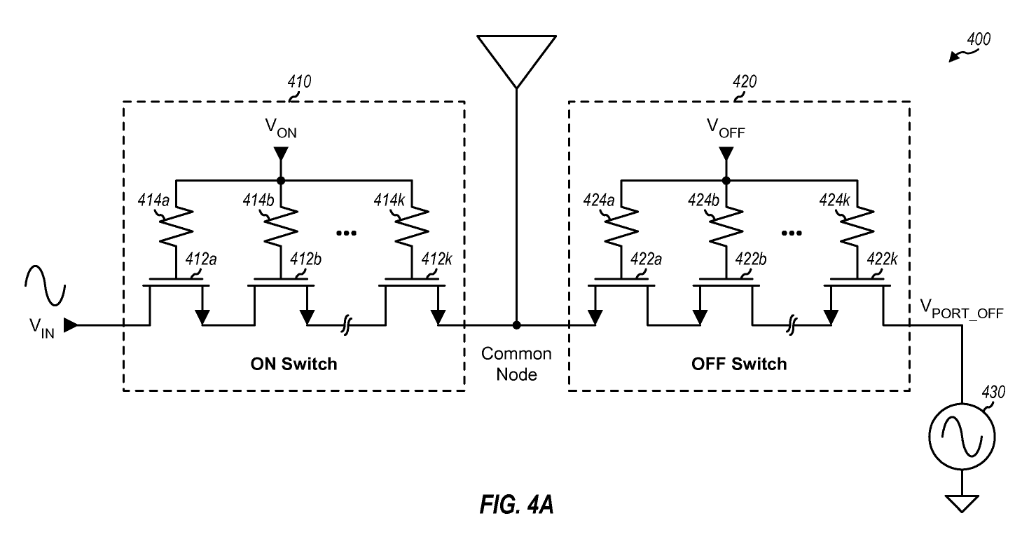

FIG. 4A shows a schematic diagram of a circuit 400 comprising two switches 410 and 420 coupled to a common node. Switches 410 and 420 may be two switches in a switchplexer coupled to an antenna, as shown in FIG. 4A. Switches 410 and 420 may also be any two switches coupled to a common node in a transmitter. Additional switches may also be coupled to the common node and are not shown in FIG. 4A for simplicity. At any given moment, one or more switches coupled to the common node may be turned on, and the remaining switches coupled to the common node may be turned off.

Switch 410 has one terminal receiving an input RF signal (V_{IN}) and the other terminal coupled to the common node. Switch 420 has one terminal coupled to the common node and the other terminal coupled to a signal source 430 having a low direct current (DC) voltage, e.g., 0 Volts (V) or some other value.

Switch 410 is implemented with K stacked NMOS transistors 412a through 412k and K resistors 414a through 414k, which are coupled as described above for NMOS transistors 312a through 312k and resistors 314a through 314k in FIG. 3. Switch 420 is implemented with K stacked NMOS transistors 422a through 422k and K resistors 424a through 424k, which are coupled as described above for NMOS transistors 312a through 312k and resistors 314a through 314k in FIG. 3. In general, switches 410 and 420 may include the same or different numbers of transistors.

In FIG. 4A, switch 410 is turned on by applying a V_{ON} control voltage to the gates of NMOS transistors 412 via resistors 414. Switch 420 is turned off by applying a V_{OFF} control voltage to the gates of NMOS transistors 422 via resistors 424. The V_{ON} and V_{OFF} control voltages are typically fixed values, which may be selected based on a compromise between several factors such as insertion loss and reliability. The fixed V_{ON} and V_{OFF} control voltages may provide sub-optimal performance in certain scenarios, which may be encountered when the V_{IN} signal varies over a wide range.

In an aspect, a variable control voltage may be applied to a switch to improve reliability and possibly enhance switching performance. The control voltage may be varied (e.g., via programmable means) based on various factors such as radio technology or standard being supported, the power level of the signal observed by the switch, etc. The control voltage may be varied to achieve good performance in terms of insertion loss, reliability, linearity, isolation, etc.

FIG. 4B shows the V_{IN} signal and DC voltages for the off switch 420 in FIG. 4A. The V_{IN} signal has a peak positive voltage of V_{PEAK} and a peak negative voltage of −V_{PEAK}. The DC voltage (V_{COMMON}) at the common node is equal to the DC voltage (V_{PORT}_{_{—}}_{OFF}) at the other terminal of switch 420, and both DC voltages may be at 0 Volt (V) or circuit ground. The maximum voltage difference across the gate and source/drain terminals of NMOS transistors 422 in switch 420 is proportional to V_{DIFF}_{_{—}}_{MAX} and occurs when the V_{IN} signal is at V_{PEAK}. The minimum voltage difference across the gate and source/drain terminals of NMOS transistors 422 is proportional to V_{DIFF}_{_{—}}_{MIN} and occurs when the V_{IN} signal is at −V_{PEAK}. V_{DIFF}_{_{—}}_{MAX} is the maximum voltage difference between V_{IN} and the DC bias voltage (V_{OFF}) at the gate of NMOS transistors 422. V_{DIFF}_{_{—}}_{MIN} is the minimum voltage difference between V_{IN} and the DC bias voltage (V_{OFF}) at the gate of NMOS transistors 422.

In an exemplary design, a V_{OFF} control voltage to turn off a switch may be selected based on the following:

$$\begin{matrix}\frac{{V}_{PEAK}}{2 K} - {V}_{OFF} < {V}_{BREAKDOWN} , and & Eq ( 1 ) \\ \frac{{V}_{PEAK}}{2 K} + {V}_{OFF} < {V}_{TH} , & Eq ( 2 )\end{matrix}$$

where V_{BREAKDOWN} is a breakdown voltage of an NMOS transistor,

V_{TH} is a threshold voltage of the NMOS transistor, and

K is the number of stacked NMOS transistors used for the switch.

Equation (1) shows the condition to avoid breakdown of the NMOS transistors in the switch. Equation (2) shows the condition to keep the NMOS transistors in the off state. In equations (1) and (2), the voltage difference across the two terminals of the switch is assumed to be split/distributed evenly across the parasitic C_{GS} and C_{GD} capacitors of the K NMOS transistors in the switch, so that a voltage drop of V_{PEAK}/2 K is present across each parasitic capacitor. As shown in FIG. 4B, the V_{OFF} control voltage determines V_{DIFF}_{_{—}}_{MAX} as well as V_{DIFF}_{_{—}}_{MIN}. Increasing the V_{OFF} control voltage may result in the NMOS transistors being more likely to be turned on whereas decreasing the V_{OFF} control voltage may result in the NMOS transistors being more likely to exceed the breakdown voltage. The V_{OFF} control voltage may be selected such that equation (1) is satisfied to avoid breakdown of the NMOS transistors. The V_{OFF} control voltage may also be selected such that equation (2) is satisfied to ensure that the NMOS transistors are turned off.

As shown in equation (1), increasing the V_{OFF} control voltage may improve reliability. However, as shown in equation (2), increasing the V_{OFF} control voltage may also result in a weaker off condition.

A variable V_{OFF} control voltage may be applied to the switch to improve reliability and/or off condition when applicable. The peak voltage may be related to the power of the signal applied to the switch. It may be desirable to avoid breakdown of the NMOS transistors in order to improve reliability. The risk of breakdown may increase with increasing power or peak voltage. Hence, the V_{OFF} control voltage may be increased for higher peak voltage to improve reliability. For example, the V_{OFF} control voltage may be a negative DC voltage and may be made less negative for higher peak voltage to improve reliability. Conversely, at low power, V_{OFF} may be decreased to improve the off condition of the NMOS transistors.

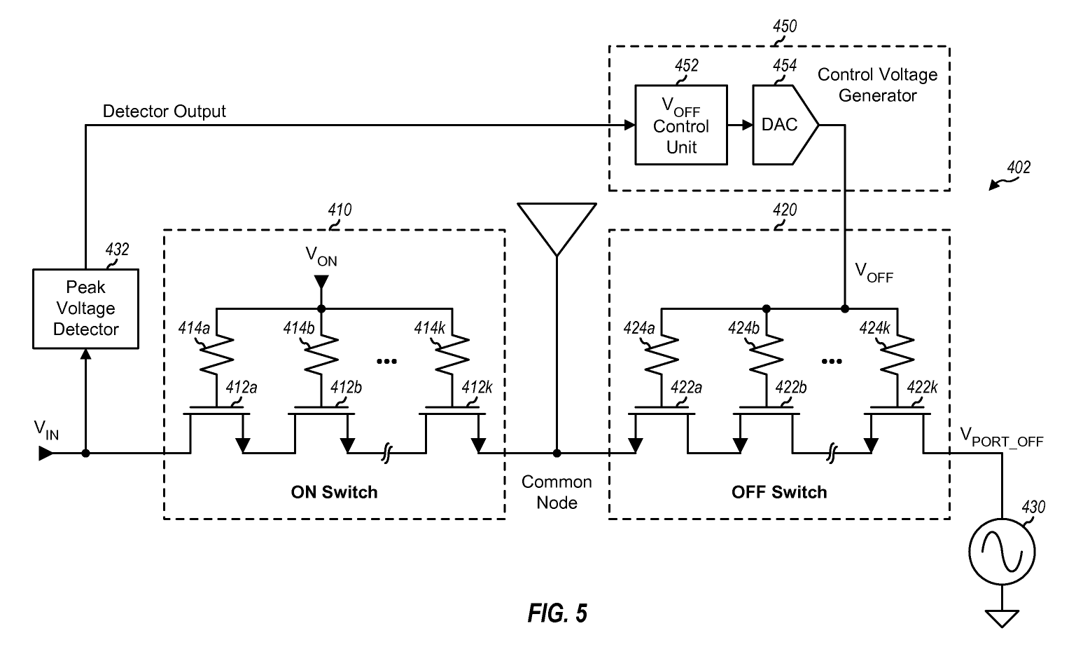

FIG. 5 shows a schematic diagram of an exemplary design of a circuit 402 comprising switches 410 and 420, with switch 420 having a variable V_{OFF} control voltage. Switches 410 and 420 are coupled to the common node and are implemented with NMOS transistors and resistors, as described above for FIG. 4A. Switch 410 is turned on by applying the V_{ON} control voltage to the gates of NMOS transistors 412 via resistors 414. Switch 420 is turned off by applying the V_{OFF} control voltage to the gates of NMOS transistors 422 via resistors 424. Switch 410 receives and passes the V_{IN} signal to the common node. Switch 420 observes the V_{IN} signal at one terminal and the V_{PORT}_{_{—}}_{OFF} voltage at the other terminal.

A peak voltage detector 432 receives the V_{IN} signal, detects for a peak voltage of the V_{IN} signal, and provides a detector output indicative of the detected peak voltage. A control voltage generator 450 receives the detector output and generates the V_{OFF} control voltage for switch 420. In the exemplary design shown in FIG. 5, generator 450 includes a V_{OFF} control unit 452 and a digital-to-analog converter (DAC) 454. Control unit 452 receives the detector output as well as an on/off control for switch 420 and generates a digital control indicative of a selected V_{OFF} control voltage for switch 420. DAC 454 receives the digital control from unit 452 and generates the V_{OFF} control voltage.

FIG. 5 shows an exemplary design of generating a variable V_{OFF} control voltage using a DAC. A variable V_{OFF} control voltage may also be generated in other manners, e.g., with programmable voltages obtained via a resistor ladder, with an analog circuit that receives the V_{IN} signal and provides the V_{OFF} control voltage, etc.

In general, the V_{OFF} control voltage may be generated based on any function of any set of parameters. In an exemplary design, the V_{OFF} control voltage may be generated as follows:

V_{OFF}=∫(V_{PEAK},V_{TH},V_{BREAKDOWN},K), Eq (3)

where ∫( ) may be any suitable function for the V_{OFF} control voltage. V_{OFF} may be (i) progressively increased for progressively higher peak voltage in order to improve reliability of NMOS transistors 422 and (ii) progressively decreased for progressively lower peak voltage in order to more fully turn off NMOS transistors 422. The V_{OFF} control voltage may also be constrained so that equations (1) and (2) are satisfied to avoid breakdown of NMOS transistor 422 and to ensure that these NMOS transistors are turned off.

The V_{OFF} control voltage may also be generated based on other factors. For example, the V_{OFF} control voltage may be generated to improve linearity of switch 420. Switch 420 may act as a nonlinear capacitor when it is turned off. The V_{OFF} control voltage may be generated such that second, third, and/or other harmonics of the V_{IN} signal at the common node are lower. The amplitude of the harmonics versus the V_{OFF} control voltage may be characterized via computer simulation, empirical measurement, etc. Function ∫( ) may be defined based on this characterization to generate the V_{OFF} control voltage such that harmonics are reduced to improve linearity.

A variable V_{ON} control voltage may also be applied to a switch to improve on condition. It may be desirable to increase the V_{ON} control voltage when the peak voltage is higher in order to reduce insertion loss.

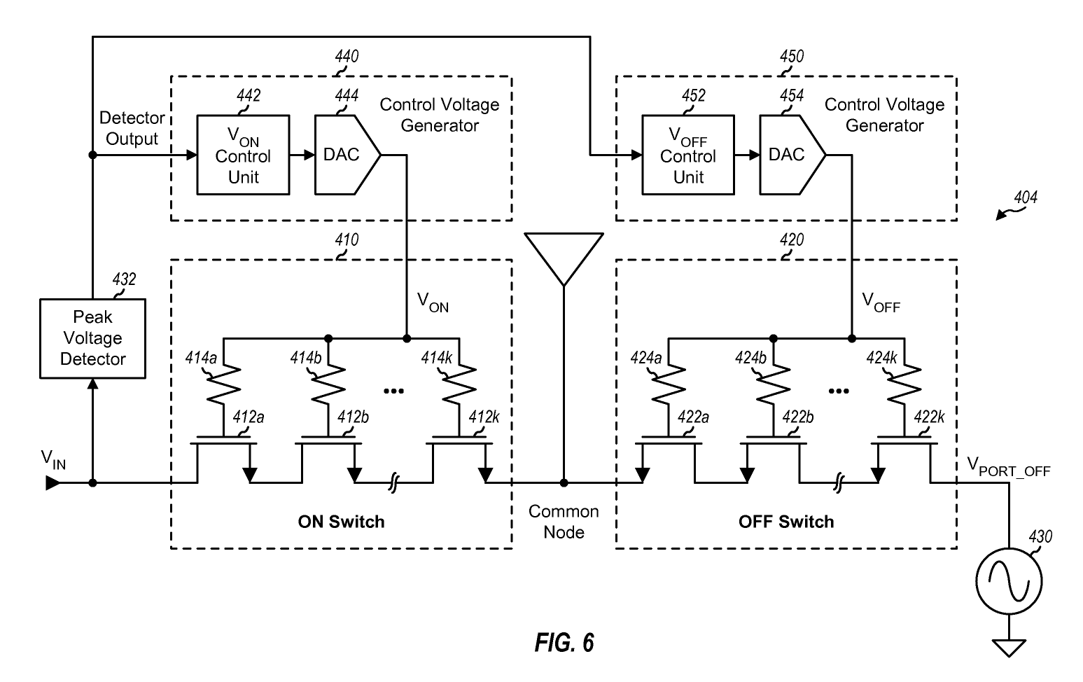

FIG. 6 shows a schematic diagram of an exemplary design of a circuit 404 comprising switches 410 and 420, with switch 410 having a variable V_{ON} control voltage and switch 420 having a variable V_{OFF} control voltage. Circuit 404 includes peak voltage detector 432 as well as control voltage generator 450, as described above for FIG. 5. Circuit 404 further includes a control voltage generator 440 for switch 410. Generator 440 receives the detector output from peak voltage detector 432 as well as an on/off control for switch 410 and generates the V_{ON} control voltage for switch 410. In the exemplary design shown in FIG. 6, generator 440 includes a V_{ON} control unit 442 and a DAC 444. Control unit 442 receives the detector output and generates a digital control indicative of a selected V_{ON} control voltage for switch 410. DAC 444 receives the digital control from unit 442 and generates the V_{ON} control voltage. A variable V_{ON} control voltage may also be generated in other manners, e.g., with programmable voltages obtained via a resistor ladder.

In general, the V_{ON} control voltage may be generated based on any function of any set of parameters. In an exemplary design, the V_{ON} control voltage may be generated as follows:

V_{ON}=g(V_{PEAK},V_{TH},V_{BREAKDOWN},K) (4)

where g( ) may be any suitable function for the V_{ON} control voltage. The V_{ON} control voltage may be progressively increased for progressively higher peak voltage in order to reduce insertion loss via NMOS transistors 412. The V_{ON} control voltage may also be constrained within a target range of values.

The V_{ON} control voltage may also be generated based on other factors. For example, the V_{ON} control voltage may be generated to improve linearity of switch 410. The V_{ON} control voltage may be generated such that second, third, and/or other harmonics of the V_{IN} signal are lower. The amplitude of the harmonics versus the V_{ON} control voltage may be characterized via computer simulation, empirical measurement, etc. Function g( ) may be defined based on this characterization to generate the V_{ON} control voltage such that harmonics are reduced to improve linearity.

A peak voltage at a common node may increase by a large amount due to a sudden change in voltage standing wave radio (VSWR) at the common node. For example, the common node may be coupled to an antenna. Disturbances may arise from human contact by a user based on proximity of hands, ears, and/or other body parts on the antenna. Disturbances may also result from the antenna becoming disconnected or shorted. In any case, the disturbances may drastically change the load impedance observed by a power amplifier and may lead to a larger voltage swing. Each switch that is coupled to the common node and is turned off would need to withstand the larger voltage swing without experiencing long/short term reliability issues. This may be achieved by implementing each switch with more stacked MOS transistors, so that a smaller voltage drop appears across each MOS transistor. However, insertion loss and overall efficiency may be worse by using more MOS transistors for each switch.

In another aspect, a switch that is coupled to a common node and is turned off may be switched on when a large voltage swing due to a sudden change in VSWR is detected. The switch may then shunt a signal at the common node to circuit ground, which would then reduce the voltage swing and avoid damage to MOS transistors.

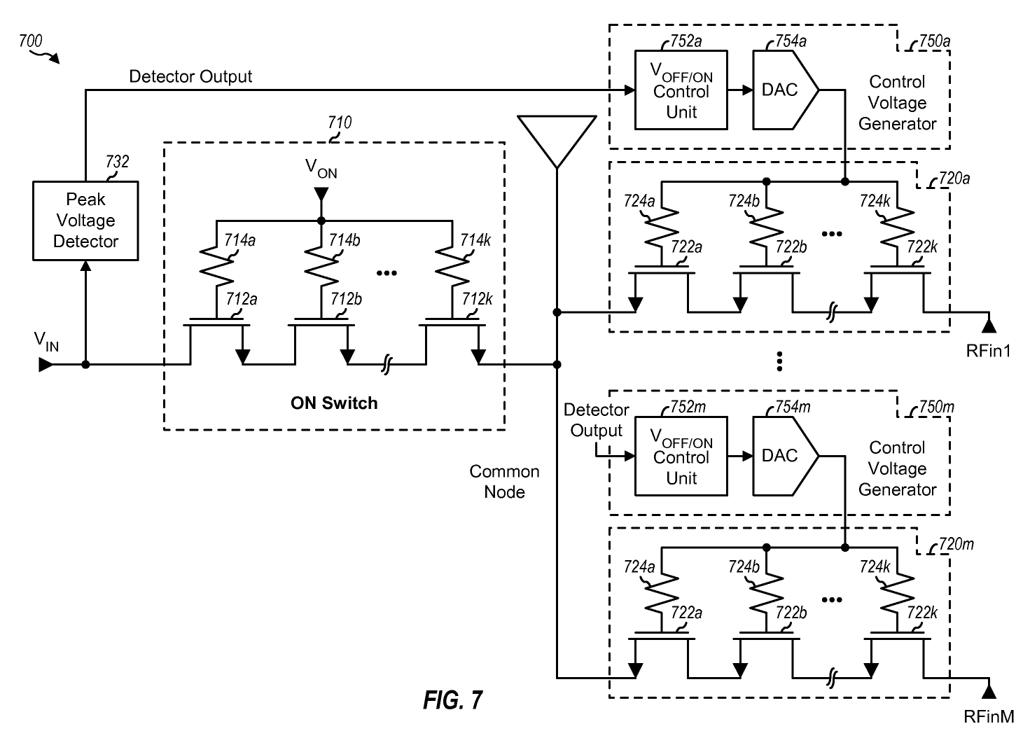

FIG. 7 shows a schematic diagram of an exemplary design of a circuit 700 comprising a switch 710 that is turned on and M switches 720a through 720m that are turned off initially, where M may be any integer value equal to or greater than one. Switch 710 and switches 720a through 720m are coupled to a common node. Switch 710 has one terminal receiving an input RF signal (V_{IN}) and the other terminal coupled to the common node. Each switch 720 has one terminal coupled to the common node and the other terminal coupled to a different RF port input, RFin, which may be alternating current (AC) ground. Switches 720 that are turned off may be used to shunt the V_{IN} signal to AC ground, if necessary.

Switch 710 is implemented with K NMOS transistors 712a through 712k and K resistors 714a through 714k, which are coupled in similar manner as NMOS transistors 412a through 412k and resistors 414a through 414k in FIG. 4A. Each switch 720 is implemented with K NMOS transistors 722a through 722k and K resistors 724a through 724k, which are coupled in similar manner as NMOS transistors 422a through 422k and resistors 424a through 424k in FIG. 4A.

Switch 710 is turned on by applying a V_{ON} control voltage to the gates of NMOS transistors 712 via resistors 714. Each switch 720 is turned off by applying a V_{OFF} control voltage to the gates of NMOS transistors 722 via resistors 724. Switch 710 receives and passes the V_{IN} signal to the common node. Each switch 720 observes the V_{IN} signal at one terminal and AC ground at the other terminal.

A peak voltage detector 732 receives the V_{IN} signal, detects for a peak voltage of the V_{IN} signal, and provides a detector output indicative of the detected peak voltage. In the exemplary design shown in FIG. 7, each switch 720 is associated with a control voltage generator 750 that generates a V_{ON/OFF} control voltage for that switch. Each generator 750 receives the detector output from peak voltage detector 732 as well as an on/off control for the associated switch 720 and generates the V_{ON/OFF} control voltage for the associated switch 720. In the exemplary design shown in FIG. 7, each generator 750 includes a V_{ON/OFF} control unit 752 and a DAC 754. Control unit 752 receives the detector output and generates a digital control indicative of a selected V_{ON/OFF} control voltage for the associated switch 720. DAC 754 receives the digital control from unit 752 and generates the V_{ON/OFF} control voltage. A variable V_{ON/OFF} control voltage may also be generated in other manners. For example, a common control unit may receive the detector output as well as the on/off controls for all M switches 720 and may generate digital controls for M DACs 754, which may then generate M V_{ON/OFF} control voltages for the M switches 720.

Each control unit 752 may determine whether the detected peak voltage is too large due to a sudden change in VSWR at the common node. For a given output power level, the V_{IN} signal may vary over a first range of values due to peak to average power ratio (PAPR) of the V_{IN} signal. The V_{IN} signal may vary over a second range of values due to a sudden change in VSWR at the common node. The second range may be much larger than the first range. Hence, a sudden change in VSWR may be declared if the peak voltage exceeds a high threshold. As an example, for a given output power level, the peak voltage may reach 10V for a particular PAPR. If the peak voltage exceeds 10V, then a sudden change in VSWR may be declared. In general, the high threshold may be set sufficiently high so that normal variation in the V_{IN} signal due to PAPR will not result in declaration of a sudden change in VSWR. This high threshold may be set sufficiently low so that the peak voltage does not need to be too large before a sudden change in VSWR can be declared.

When the peak voltage is too large (e.g., larger than the high threshold) due to a sudden change in VSWR, one or more of switches 720a through 720m may be turned on, and the V_{IN} signal may be shunted to circuit ground via each switch 720 that is turned on. Each switch 720 that is turned on can attenuate the V_{IN} signal and prevent the peak voltage from becoming too large. The amount of attenuation may be variable or programmable. For example, the peak voltage may be compared against multiple high thresholds. Progressively more attenuation may be applied when the peak voltage exceeds progressively higher threshold.

Variable attenuation may be achieved in various manners. In an exemplary design, each switch 720 that is turned on may be turned on progressively harder with a progressively larger V_{ON/OFF} control voltage for progressively larger peak voltage. In another exemplary design, different number of switches 720 or different combinations of switches 720 may be turned on depending on the detected peak voltage. For example, progressively more switches 720 may be turned on for progressively larger peak voltage. For both exemplary designs, there may be little or no performance impact since extra blocks are not needed to attenuate the V_{IN} signal. Furthermore, enhanced switching performance may be achieved since each switch can be designed with fewer stacked MOS transistors without exceeding specified voltages even with a sudden change in VSWR.

Function ∫( ) in equation (3) may be defined to provide (i) progressively smaller control voltage for progressively lower peak voltage in order to more fully turn off NMOS transistors 722, (ii) progressively larger control voltage for progressively higher peak voltage in order to improve reliability of NMOS transistors, and (iii) even larger control voltage to turn on NMOS transistor 722 for even larger peak voltage in order to attenuate the V_{IN} signal. Function ∫( ) may thus provide progressively higher control voltage for progressively higher peak voltage. Function ∫( ) may be a linear function. Function ∫( ) may also be a nonlinear function that may have discontinuity for each high threshold used to detect for a sudden change in VSWR.

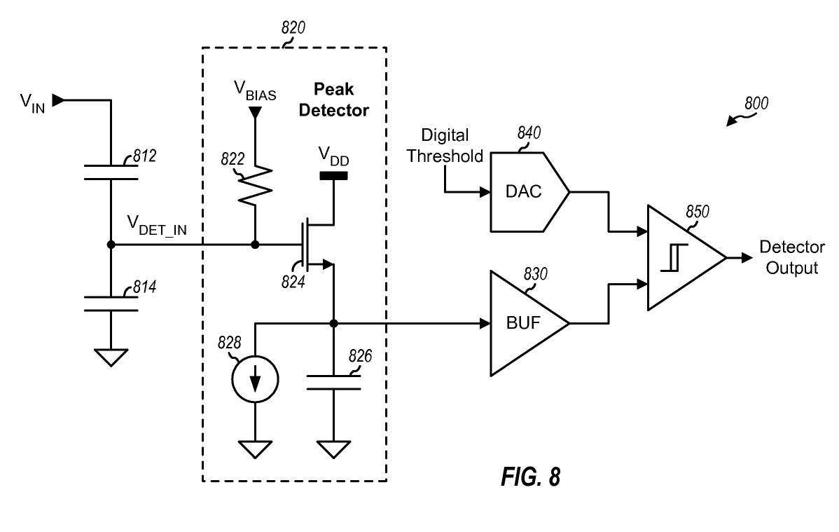

FIG. 8 shows a block diagram of an exemplary design of a peak voltage detector 800, which may be used for peak voltage detector 432 in FIGS. 5 and 6 and for peak voltage detector 732 in FIG. 7. Within peak voltage detector 800, capacitors 812 and 814 are coupled in series, with the top end of capacitor 812 receiving the V_{IN} signal, and the bottom end of capacitor 814 being coupled to circuit ground. Capacitors 812 and 814 operate as a power coupler and also as a voltage divider that can provide a detector input signal (V_{DET}_{_{—}}_{IN}) to a peak detector 820. The V_{DET}_{_{—}}_{IN} signal is an attenuated version of the V_{IN} signal, which may be large during a sudden change in VSWR. The voltage divider protects peak detector 820 from high voltage during the sudden change in VSWR.

Peak detector 820 detects a peak voltage of the V_{DET}_{_{—}}_{IN} signal and provides a detected signal indicative of the detected peak voltage. Within peak detector 820, a resistor 822 has one end receiving a bias voltage (V_{BIAS}) and the other end coupled to the gate of an NMOS transistor 824, which has its drain coupled to a power supply (V_{DD}). NMOS transistor 824 also receives the V_{DET}_{_{—}}_{IN} signal at its gate and provides the detected signal at its source. The V_{IN} signal observes a high-pass filter formed by capacitors 812 and 814 and resistor 822. A capacitor 826 and a current source 828 are coupled between the source of NMOS transistor 824 and circuit ground. Current source 828 provides a bias current of I_{B}. NMOS transistor 824 acts as a rectifying forward-biased diode and commutates charge on to capacitor 826 to obtain a positive rectified voltage. To make the charge transfer onto capacitor 826 bi-directional, current source 828 acts as a constant current sink so that peak detector 820 can respond to a time-varying waveform.

A buffer 830 buffers the detected signal from peak detector 820 and prevents charge leakage from capacitor 826. A DAC 840 receives a digital control (e.g., a digital threshold) and generates a threshold voltage based on the digital control. DAC 840 can generate different threshold voltages in response to different digital control values. A comparator 850 receives the output voltage from buffer 830 and the threshold voltage from DAC 840, compares the two voltages, and generates the detector output based on the result of the comparison.

FIG. 8 shows an exemplary design of a peak voltage detector. A peak voltage detector may also be implemented in other manners. A peak voltage detector may detect for a peak voltage in an input signal, e.g., as shown in FIG. 8. A peak voltage detector may also detect for a root mean square (RMS) voltage of an input signal or both a peak voltage and an RMS voltage of the input signal. In general, a peak voltage detector may detect for a magnitude of an input signal, which may be given by a peak voltage, an RMS voltage, etc. The output of the peak voltage detector may be used to generate variable control voltages for switches.

In the exemplary designs shown in FIGS. 5 to 7, a control voltage generator may include a control unit to receive a detector output from a peak voltage detector and generate a digital control for an associated DAC. The control unit may be implemented in various manners. In one exemplary design, the control unit may be implemented with one or more look-up tables that can receive the detector output and provide the corresponding digital control. For example, one look-up table may be used when a switch is turned on, and another look-up table may be used when the switch is turned off. In another design, the control unit may be implemented with digital logic. In yet another exemplary design, the control unit may be implemented by a processor, e.g., data processor 110 in FIG. 1. The control unit may also be implemented in other manners.

In an exemplary design, an apparatus may comprise a switch, a peak voltage detector, and a control voltage generator, e.g., as shown in FIG. 5. The switch (e.g., switch 420) may be implemented with stacked MOS transistors and resistors coupled to the gates of the MOS transistors. The switch may receive an input signal at one terminal and may be turned off. The peak voltage detector may detect a peak voltage of the input signal, e.g., based on a peak voltage measurement and/or an RMS measurement of the input signal. The control voltage generator may generate a variable control voltage to turn off the switch based on the detected peak voltage. In an exemplary design, the control voltage generator may comprise a control unit and a DAC, e.g., as shown in FIG. 5. The control unit may generate a digital control based on the detected peak voltage. The DAC may receive the digital control and generate the variable control voltage for the switch. The control voltage generator may also be implemented in other manners. In any case, the control voltage generator may generate the variable control voltage based on a function of at least one parameter, which may comprise the detected peak voltage, a threshold voltage, a breakdown voltage, etc. The variable control voltage may have progressively larger magnitude for progressively larger detected peak voltage.

In another exemplary design, an apparatus may comprise a switch, a peak voltage detector, and a control voltage generator, e.g., as shown in FIG. 6. The switch (e.g., switch 410) may receive an input signal at one terminal and may be turned on. The peak voltage detector may detect a peak voltage of the input signal. The control voltage generator may generate a digital control based on the detected peak voltage and may generate a variable control voltage to turn on the switch based on the digital control. The variable control voltage may have progressively larger magnitude for progressively larger detected peak voltage in order to reduce insertion loss.

In yet another exemplary design, an apparatus may comprise a switch, a peak voltage detector, and a control voltage generator, e.g., as shown in FIG. 7. The switch (e.g., switch 720a) may receive an input signal at one terminal. The peak voltage detector may detect a peak voltage of the input signal. The control voltage generator may generate a control voltage to turn off or on the switch based on the detected peak voltage. The switch may block the input signal when it is turned off and may attenuate the input signal when it is turned on.

The control voltage generator may generate the control voltage to (i) turn off the switch when the detected peak voltage is below a first level and (ii) turn on the switch when the detected peak voltage is above a second level. The second level may be equal to or higher than the first level. The switch may abruptly or gradually go from an off state to an on state. The first and second levels may be determined by thresholds used to detect the peak voltage. The first and second levels may also correspond to values in a function of control voltage versus detected peak voltage. The control voltage generator may generate (i) a fixed off control voltage for the switch or (ii) a variable off control voltage based on the detected peak voltage to turn the switch off. The control voltage generator may also generate (i) a fixed on control voltage for the switch or (ii) a variable on control voltage based on the detected peak voltage, to turn the switch on. The variable on control voltage may turn on the switch progressively more, to provide more attenuation, for progressively larger detected peak voltage above the second level.

The apparatus may comprise at least one additional switch, which may receive the input signal at one terminal, e.g., as shown in FIG. 7. One or more of the switches may be turned on when the detected peak voltage is above the second level. For example, progressively more switches may be turned on for progressively larger detected peak voltage above the second level.

In yet another exemplary design, an integrated circuit may comprise first and second switches coupled to a common node, e.g., as shown in FIG. 5, 6 or 7. The switches may be part of a switchplexer or may be other switches within a transmitter. The second switch may be turned off by a variable control voltage, which may be generated based on a peak voltage at the common node. The second switch may also be turned on by the variable control voltage when the peak voltage exceeds a particular level. The first switch may be turned on, e.g., by a fixed control voltage or another variable control voltage generated based on the peak voltage. The integrated circuit may further comprise a peak voltage detector and a control voltage generator. The peak voltage detector may detect the peak voltage. The control voltage generator may generate the variable control voltage for the second switch based on the detected peak voltage. Another control voltage generator may generate another variable control voltage for the first switch based on the detected peak voltage.

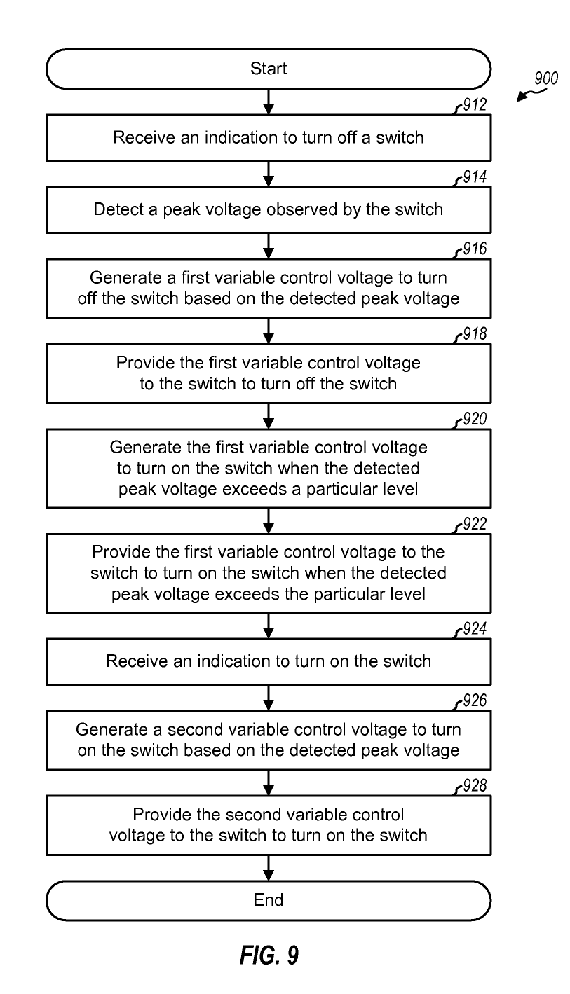

FIG. 9 shows an exemplary design of a process 900 for controlling a switch. An indication to turn off the switch may be received (block 912). A peak voltage observed by the switch may be detected (block 914). A first variable control voltage to turn off the switch may be generated based on the detected peak voltage (block 916). In an exemplary design of block 916, a digital control may be generated based on the detected peak voltage. The first variable control voltage for the switch may then be generated based on the digital control. The first variable control voltage may also be generated in other manners. The first variable control voltage may have progressively larger magnitude for progressively larger detected peak voltage. The first variable control voltage may be provided to the switch to turn off the switch (block 918).

When the detected peak voltage exceeds a particular level, the first variable control voltage may be generated to turn on the switch (block 920). The first variable control voltage may then be provided to the switch to turn on the switch and provide attenuation (block 922).

An indication to turn on the switch may be received (block 924). A second variable control voltage to turn on the switch may be generated based on the detected peak voltage (block 926). The second variable control voltage may be provided to the switch to turn on the switch (block 928).

The switches with variable control voltages described herein may be implemented on an IC, an analog IC, an RFIC, a mixed-signal IC, an ASIC, a printed circuit board (PCB), an electronics device, etc. The switches may also be fabricated with various IC process technologies such as complementary metal oxide semiconductor (CMOS), NMOS, PMOS, bipolar junction transistor (BJT), bipolar-CMOS (BiCMOS), silicon germanium (SiGe), gallium arsenide (GaAs), etc. The switches may also be fabricated with silicon-on-insulator (SOI), which is an IC process in which a thin layer of silicon is formed on top of an insulator such as silicon oxide or glass. MOS transistors for the switches may then be built on top of this thin layer of silicon. The SOI process may reduce parasitic capacitances of the switches, which may be able faster operation.

An apparatus implementing the switches with variable control voltages described herein may be a stand-alone device or may be part of a larger device. A device may be (i) a stand-alone IC, (ii) a set of one or more ICs that may include memory ICs for storing data and/or instructions, (iii) an RFIC such as an RF receiver (RFR) or an RF transmitter/receiver (RTR), (iv) an ASIC such as a mobile station modem (MSM), (v) a module that may be embedded within other devices, (vi) a receiver, cellular phone, wireless device, handset, or mobile unit, (vii) etc.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

The previous description of the disclosure is provided to enable any person skilled in the art to make or use the disclosure. Various modifications to the disclosure will be readily apparent to those skilled in the art, and the generic principles defined herein may be applied to other variations without departing from the scope of the disclosure. Thus, the disclosure is not intended to be limited to the examples and designs described herein but is to be accorded the widest scope consistent with the principles and novel features disclosed herein.

What is claimed is:

1. An apparatus comprising:
a switch to receive an input signal at one terminal and is turned off;
a peak voltage detector to detect a peak voltage of the input signal; and
a control voltage generator to generate a variable control voltage to turn off the switch based on the detected peak voltage.

2. The apparatus of claim 1, the control voltage generator comprises
a control unit to generate a digital control based on the detected peak voltage, and
a digital-to-analog converter (DAC) to receive the digital control and generate the variable control voltage for the switch.

3. The apparatus of claim 1, the control voltage generator generates the variable control voltage based on a function of at least one parameter comprising the detected peak voltage.

4. The apparatus of claim 3, the switch comprises at least one metal oxide semiconductor (MOS) transistor, and the at least one parameter further comprises a threshold voltage, or a breakdown voltage, or both for the at least one MOS transistor.

5. The apparatus of claim 1, the variable control voltage has progressively larger magnitude for progressively larger detected peak voltage.

6. The apparatus of claim 1, the switch comprises
a plurality of metal oxide semiconductor (MOS) transistors coupled in a stacked configuration, and
a plurality of resistors coupled to gates of the plurality of MOS transistors, the variable control voltage is applied to the gates of the plurality of MOS transistors via the plurality of resistors.

7. The apparatus of claim 1, the peak voltage detector detects the peak voltage of the input signal based on a peak voltage measurement, or a root mean square (RMS) measurement, or both peak voltage and RMS measurements of the input signal.

8. An apparatus comprising:
a switch to receive an input signal at one terminal and is turned on;
a peak voltage detector to detect a peak voltage of the input signal; and
a control voltage generator to generate a digital control based on the detected peak voltage and to generate a variable control voltage to turn on the switch based on the digital control.

9. The apparatus of claim 8, the control voltage generator comprises
a control unit to generate the digital control based on the detected peak voltage, and
a digital-to-analog converter (DAC) to receive the digital control and generate the variable control voltage for the switch.

10. The apparatus of claim 8, the variable control voltage has progressively larger magnitude for progressively larger detected peak voltage.

11. An apparatus comprising:
a switch to receive an input signal at one terminal;
a peak voltage detector to detect a peak voltage of the input signal; and
a control voltage generator to generate a control voltage to turn off or on the switch based on the detected peak voltage.

12. The apparatus of claim 11, the switch blocks the input signal when turned off and attenuates the input signal when turned on.

13. The apparatus of claim 11, the control voltage generator generates the control voltage to turn off the switch when the detected peak voltage is below a first level and to turn on the switch when the detected peak voltage is above a second level, the second level is equal to or higher than the first level.

14. The apparatus of claim 13, the control voltage generator generates a variable control voltage to turn off the switch based on the detected peak voltage when the detected peak voltage is below the first level.

15. The apparatus of claim 13, the control voltage generator generates a variable control voltage to turn on the switch based on the detected peak voltage when the detected peak voltage is above the second level.

16. The apparatus of claim 15, the variable control voltage turns on the switch progressively more, to provide more attenuation, for progressively larger detected peak voltage above the second level.

17. The apparatus of claim 11, further comprising:
at least one additional switch to receive the input signal at one terminal, one or more of the switch and the at least one additional switch are turned on when the detected peak voltage is above a particular level.

18. The apparatus of claim 17, progressively more switches are turned on for progressively larger detected peak voltage above the particular level.

19. The apparatus of claim 11, the control voltage generator comprises
a control unit to generate a digital control based on the detected peak voltage, and
a digital-to-analog converter (DAC) to receive the digital control and generate the control voltage for the switch.

20. An integrated circuit comprising:
a first switch coupled to a common node and is turned on; and
a second switch coupled to the common node and is turned off by a variable control voltage generated based on a peak voltage at the common node.

21. The integrated circuit of claim 20, the first switch is turned on by a second variable control voltage generated based on the peak voltage.

22. The integrated circuit of claim 20, the second switch is turned on by the variable control voltage when the peak voltage exceeds a particular level.

23. The integrated circuit of claim 20, further comprising:
a peak voltage detector to detect the peak voltage; and
a control voltage generator to generate the variable control voltage for the second switch based on the detected peak voltage.

24. A method of controlling a switch, comprising:
receiving an indication to turn off the switch;
detecting a peak voltage observed by the switch;
generating a first variable control voltage to turn off the switch based on the detected peak voltage; and
providing the first variable control voltage to the switch to turn off the switch.

25. The method of claim 24, the generating the first variable control voltage comprises
generating a digital control based on the detected peak voltage, and
generating the first variable control voltage for the switch based on the digital control.

26. The method of claim 24, the first variable control voltage has progressively larger magnitude for progressively larger detected peak voltage.

27. The method of claim 24, further comprising:
generating the first variable control voltage to turn on the switch when the detected peak voltage exceeds a particular level; and
providing the first variable control voltage to the switch to turn on the switch when the detected peak voltage exceeds the particular level.

28. The method of claim 24, further comprising:
receiving an indication to turn on the switch;
generating a second variable control voltage to turn on the switch based on the detected peak voltage; and
providing the second variable control voltage to the switch to turn on the switch.

29. An apparatus for controlling a switch, comprising:
means for receiving an indication to turn off the switch;
means for detecting a peak voltage observed by the switch;
means for generating a first variable control voltage to turn off the switch based on the detected peak voltage; and
means for providing the first variable control voltage to the switch to turn off the switch.

30. The apparatus of claim 29, further comprising:
means for generating the first variable control voltage to turn on the switch when the detected peak voltage exceeds a particular level; and
means for providing the first variable control voltage to the switch to turn on the switch when the detected peak voltage exceeds the particular level.

31. The apparatus of claim 29, further comprising:
means for receiving an indication to turn on the switch;
means for generating a second variable control voltage to turn on the switch based on the detected peak voltage; and
means for providing the second variable control voltage to the switch to turn on the switch.
